(19) United States
(12) Patent Application Publication
(10) Pub. No.: US 2021/0313500 A1
(43) Pub. Date: Oct. 7, 2021

(54) OPTOELECTRONIC SEMICONDUCTOR CHIP, OPTOELECTRONIC COMPONENT AND METHOD OF MANUFACTURING AN OPTOELECTRONIC COMPONENT

(71) Applicant: Osram OLED GmbH, Regensburg (DE)

(72) Inventors: Andreas Leber, Regensburg (DE); Siegfried Herrmann, Neukirchen (DE); Christine Rafael, Donaustauf (DE)

(21) Appl. No.: 17/266,631

(22) PCT Filed: Jul. 23, 2019
(86) PCT No.: PCT/EP2019/069809

§ 371 Date: Feb. 8, 2021

(30) Foreign Application Priority Data
Aug. 9, 2018 (DE) 10 2018 119 438.2

(51) Int. Cl. H01L 33/62; H01L 25/075; H01L 33/50; H01L 33/00; H01L 33/60; H01L 33/10

(52) U.S. Cl. CPC H01L 33/62; H01L 25/0753; H01L 33/505; H01L 33/005; H01L 2933/0066; H01L 33/10; H01L 2933/0041; H01L 2933/0058; H01L 33/60

(57) ABSTRACT

An optoelectronic semiconductor chip may include a substrate and a semiconductor layer sequence having a first region, a second region, and an active layer between the first and second region. The chip may further include a first contact ridge configured to energize a first region, a second contact ridge configured to energize the second region, a first connection point to contact the first contact ridge, and a second connection point to contact the second contact ridge. The first and second contact ridge may each extend over at least 50% of the length of the semiconductor chip. The first and second contact ridge may vertically overlap where at least one through-connection extends from the first contact ridge through the second contact ridge into the first region.

### CROSS-REFERENCE TO RELATED APPLICATIONS

The present application is a national stage entry according to 35 U.S.C. § 371 of PCT application No.: PCT/EP2019/069809 filed on Jul. 23, 2019; which claims priority to German Patent Application Serial No.: 10 2018 119 438.2 filed on Aug. 9, 2018; all of which are incorporated herein by reference in their entirety and for all purposes.

### TECHNICAL FIELD

An optoelectronic semiconductor chip is disclosed, an optoelectronic component, as well as a method of manufacturing an optoelectronic component.

### BACKGROUND

It is an object of the present disclosure to specify an optoelectronic semiconductor chip that can be operated particularly efficiently. Another object is to specify an optoelectronic component comprising such an optoelectronic semiconductor chip. Further, it is an object to specify a method of manufacturing such an optoelectronic component.

### SUMMARY

An optoelectronic semiconductor chip is specified. The optoelectronic semiconductor chip can, for example, be a radiation-emitting semiconductor chip, which generates electromagnetic radiation, for example light, during operation. The optoelectronic semiconductor chip can then be a light-emitting diode chip in particular. It is also possible that the optoelectronic semiconductor chip is a radiation-receiving semiconductor chip that detects electromagnetic radiation during operation. The optoelectronic semiconductor chip is then a photodiode chip, for example.

According to at least one embodiment, the optoelectronic semiconductor chip comprises a substrate that is transmissive for radiation. The substrate is the mechanically supporting component of the optoelectronic semiconductor chip, which mechanically carries and supports the other components of the optoelectronic semiconductor chip. For example, the substrate can be a growth substrate on which further layers of the optoelectronic semiconductor chip are epitaxially deposited. Furthermore, the substrate can be a carrier on which further layers of the optoelectronic semiconductor chip are applied. The substrate is transmissive for radiation. This means that the substrate is especially transmissive for electromagnetic radiation generated or to be detected in the optoelectronic semiconductor chip during operation. For example, the substrate can be transparent or diffusely scattering. For example, the substrate is formed with glass and/or sapphire or consists of one of these materials.

The substrate can be cylindrical or cuboidal, for example. The substrate has a top surface, a bottom surface and at least one side surface, which connect the top surface and the bottom surface. Subsequent layers of the optoelectronic semiconductor chip can be applied to the top surface, for example. Through the areas of the outer surface of the substrate not covered by further layers of the optoelectronic semiconductor chip, the electromagnetic radiation generated in the optoelectronic semiconductor chip can exit or the electromagnetic radiation to be detected can enter. These surfaces can be smooth or roughened in certain areas or completely. A roughening of the outer surface of the substrate intended for radiation exit or radiation entry may increase the probability of light exit or entry.

According to at least one embodiment, the optoelectronic semiconductor chip comprises a semiconductor layer sequence having a first region of a first conductivity type, a second region of a second conductivity type, and an active region between the first region and the second region. For example, the first region can be an n-doped region and the second region can be a p-doped region. During operation of the optoelectronic semiconductor chip, the electromagnetic radiation to be emitted is generated, or the electromagnetic radiation to be detected is detected, in the active region. The semiconductor layer sequence can be based, for example, on a III-V compound semiconductor material, such as a nitride compound semiconductor material.

According to at least one embodiment, the optoelectronic semiconductor chip comprises a first contact ridge for energizing the first region. The contact ridge is electrically connected to the first region. The first contact ridge can, for example, be directly connected to the first region or at least one through-connection is arranged between the first contact ridge and the first region.

According to at least one embodiment, the optoelectronic semiconductor chip comprises a second contact ridge for energizing the second region. The second contact ridge is electrically connected to the second region. For example, the second contact ridge is in direct contact with the second region or at least one further current expansion layer is arranged between the second contact ridge and the second region.

Both contact ridges are elongated. This means that the contact ridges have a main extension direction along which they are longer than they are wide or thick in a direction perpendicular to it. The width of the contact ridges is measured, for example, in a direction perpendicular to the main extension direction and perpendicular to a stacking direction in which the regions of the semiconductor layer sequence are applied on top of each other. Furthermore, the contact ridges are characterized in particular by a thickness, measured parallel to the stacking direction, which is small compared to the width and the length of the contact ridges. For example, the length of a contact ridge is larger than its width by at least a factor of 5, in particular at least a factor of 10, and the width of the contact ridge may be larger than the thickness of the contact ridge by at least a factor of 5, in particular at least a factor of 10.

The contact ridges may be metallic. In particular, the contact ridges can be formed with particularly ductile metals or metal alloys. For this purpose, the contact ridges can include metals such as nickel, copper and/or gold or consist of one of these materials.

Overall, the geometry and nature of the contact ridges with respect to the material of which they are made can make them particularly flexible, which can prevent breakage under mechanical stress and/or temperature variations.

According to at least one embodiment, the optoelectronic semiconductor chip comprises a first connection point for contacting the first contact ridge from outside the optoelectronic semiconductor chip, and a second connection point for contacting the second contact ridge from outside the optoelectronic semiconductor chip. Via the connection points, it is possible, for example, to mount the optoelectronic semiconductor chip using a surface mounting technique. In this case, the optoelectronic semiconductor chip can be surface mounted. The connection points are intended, for example, to be soldered or electrically conductively bonded to a carrier, such as a printed circuit board. The connection points can, for example, have a mounting surface with which the optoelectronic semiconductor chip rests at its destination. In particular, it is possible for the optoelectronic semiconductor chip to have exactly two connection points, a single first and a single second connection point.

According to at least one embodiment of the optoelectronic semiconductor chip, the first contact ridge and the second contact ridge each extend over at least 50% of the length of the semiconductor chip. For example, the semiconductor chip has a main extension direction which is perpendicular to the stacking direction of the semiconductor layer sequence. The semiconductor chip then has its greatest lateral extension along the main extension direction. The contact ridges can run parallel to the main extension direction and each of them can extend over a length of 50% of the length of the semiconductor chip. Contact ridges with such a large length allow the largest possible area of the semiconductor layer sequence to be energized. This makes it possible to apply current to the optoelectronic semiconductor chip via only a few contact ridges, in extreme cases exactly over one first and exactly one second contact ridge. The optoelectronic semiconductor chip can thus be produced with low manufacturing costs and is still particularly efficient to operate.

According to at least one embodiment, an optoelectronic semiconductor chip is specified, comprising
a substrate that is transmissive for radiation,
a semiconductor layer sequence having a first region of a first conductivity type, a second region of a second conductivity type, and an active region between the first region and the second region,
a first contact ridge for energizing the first region,
a second contact ridge for energizing the second region,
a first connection point for contacting the first contact ridge from outside the optoelectronic semiconductor chip, and
a second connection point for contacting the second contact ridge from outside the optoelectronic semiconductor chip, wherein
the first contact ridge and the second contact ridge each extend over at least 50% of the length of the semiconductor chip.

An optoelectronic semiconductor chip described here is suitable for use in an LED filament, for example. In such a filament, optoelectronic semiconductor chips are applied to a carrier along a main extension direction of the filament. An optoelectronic semiconductor chip described here can now be made particularly long, rectangular and with a large geometric aspect ratio (the ratio of length to width). In this way, a single optoelectronic semiconductor chip described here can replace several small chips. As a result, the carrier of the light thread must be equipped with fewer chips. The optoelectronic semiconductor chip described here is suitable for particularly efficient low current operation.

According to at least one embodiment of the optoelectronic semiconductor chip, the first contact ridge vertically overlaps with the second connection point and/or the second contact ridge vertically overlaps with the first connection point. In particular, it is possible that the first contact ridge also overlaps with the first connection point and the second contact ridge overlaps with the second connection point. This makes it in particular possible that both contact ridges extend so far that they overlap with both connection points. “Vertically overlap” here means that the vertically overlapping elements are arranged directly on top of each other in a vertical direction parallel to the stacking direction of the semiconductor layer sequence.

According to at least one embodiment of the optoelectronic semiconductor chip, the first contact ridge and the second contact ridge overlap vertically. This means that the two contact ridges are arranged one above the other in the semiconductor chip. This enables an optoelectronic semiconductor chip in which the contact ridges shield particularly little electromagnetic radiation. In particular, this makes it possible for the optoelectronic semiconductor chip to emit or receive electromagnetic radiation not only through the outer surfaces of the substrate, but also through the bottom surface of the semiconductor chip facing away from the substrate, where the contact ridges are also formed. In this way, the optoelectronic semiconductor chip can receive or emit electromagnetic radiation over almost its entire outer surface. This makes it possible, for example, to mount a conversion element, which can convert the primary radiation generated in the optoelectronic semiconductor chip into secondary radiation of a different wavelength, on the side of the semiconductor layer sequence facing away from the substrate, for example between the first and second connection points.

For example, the vertically overlapping contact ridges can have the same width. In this way, it is possible that they are congruently arranged one above the other at least in places.

In particular, it is possible that at least one through-connection, especially a plurality of through-connections, extends from the first contact ridge through the second contact ridge into the first region. The first contact ridge is then electrically conductively connected to the first region of the semiconductor layer sequence via the through-connection.

According to at least one embodiment of the optoelectronic semiconductor chip, the substrate has a thickness of at least 300 μm. For example, the substrate has a thickness of at least 300 and at most 700 μm. The substrate consists for example of sapphire or a glass. The use of such thick substrates is made possible, for example, by special separation techniques for separating the optoelectronic semiconductor chips. For example, the semiconductor chips are separated by laser-assisted via drilling. For a radiation-emitting optoelectronic semiconductor chip, the light extraction through the outer surface of the substrate improves with the increasing thickness of the substrate. Furthermore, the large thickness of the substrate allows to roughen the outer surface of the substrate, which is free of the semiconductor layer sequence, for example by coupled plasma etching. In this way, the probability of light exit or light entry can be further increased.

According to at least one embodiment of the optoelectronic semiconductor chip, the optoelectronic semiconductor chip comprises a mirror which is arranged between the first contact ridge and the first connection point and/or between the second contact ridge and the second connection point. The mirror can only be located vertically above the connection points. Furthermore, it is possible that the mirror extends over the entire surface on the side of the semiconductor layer sequence that is facing away from the substrate. In this case, it is not possible for light to enter and/or exit this side of the semiconductor chip. Instead, a particularly large amount of electromagnetic radiation is reflected to the uncovered outer surface of the substrate.

The mirror comprises in particular a first mirror layer which is metallic, a second mirror layer which is a Bragg mirror, and a third mirror layer which is a Bragg mirror. For example, from a connection point, the first mirror layer follows on the side of the connection point facing the semiconductor layer sequence, then the second mirror layer on the side of the first mirror layer facing away from the connection point, and then the third mirror layer on the side of the second mirror layer facing away from the connection point. The second mirror layer and the third mirror layer can each be Bragg mirrors (DBR—“Distributed Bragg Reflection” mirrors) with eight pairs of layers of TiO₂ and SiO₂ each, which are alternately arranged on top of each other. The first mirror layer can contain silver and/or aluminum, for example, or consist of one of these materials.

In other words, on the side of the second region of the semiconductor layer sequence that is facing away from the active region, the mirror follows. Between the mirror and the second region, which is for example p-conducting, a current expansion layer can be arranged, which is formed with a transparent conductive oxide (TCO) like ITO or ZnO. Subsequently, the two Bragg mirrors can be arranged, which can be covered by the metal mirror.

It is also possible that the mirror extends from the first connection point to the second connection point along the contact ridges. In particular, the mirror and the contact ridges can then overlap vertically. This means that the mirror can vertically overlap with each of the contact ridges. The width of the mirror can then also be equal to the width of the associated contact ridge except for a deviation of ±10% at most. In this way, light is reflected only in the area of the contact ridges, which reduces the absorption of electromagnetic radiation at the contact ridges.

According to at least one embodiment of the optoelectronic semiconductor chip, the first mirror layer extends through openings in the second mirror layer and the third mirror layer and provides an electrically conductive connection between the first contact ridge and the first connection point and/or between the second contact ridge and the second connection point. This means that the first mirror layer has a double function in this case: on the one hand, it reflects electromagnetic radiation that is generated or detected in the active region, and on the other hand, it serves as an electrically conductive connection between the connection point and the contact ridge associated with the connection point. The feed-throughs through the second and third mirror layers, i.e. the openings for connecting the contact ridges to the connection points, can be designed as elongated trenches or cylindrical.

Furthermore, an optoelectronic component is specified. According to at least one embodiment, the optoelectronic component comprises at least one optoelectronic semiconductor chip which is designed to emit electromagnetic radiation during operation. In particular, the optoelectronic semiconductor chip may be an optoelectronic semiconductor chip described here. This means that all features described for an optoelectronic semiconductor chip described here are also disclosed for the optoelectronic component and vice versa.

According to at least one embodiment of the optoelectronic component, the optoelectronic component comprises a first conversion element on a side of the semiconductor layer sequence facing away from the substrate of the optoelectronic semiconductor chip between the first connection point and the second connection point, and/or a second conversion element on a side of the substrate facing away from the semiconductor layer sequence. This means that the at least one optoelectronic semiconductor chip of the optoelectronic component comprises at least one conversion element which follows the semiconductor layer sequence on its side facing away from the substrate or which is applied to an outer side of the substrate. In particular, it is also possible that the optoelectronic semiconductor chip has both of these conversion elements. In the case that the optoelectronic component has two or more optoelectronic semiconductor chips, at least some of them may have a first and/or a second conversion element arranged downstream in the manner described.

“At least some” means here and in the following that the method step can be performed for at least one, more than one or all of the components.

The use of a first conversion element on a side of the semiconductor layer sequence facing away from the substrate between the first connection point and the second connection point is possible in a particularly advantageous manner if the contact ridges of the semiconductor chip are arranged vertically overlapping. In this case, the contact ridges shield particularly little electromagnetic radiation, and particularly much electromagnetic radiation reaches the underside of the semiconductor layer sequence facing away from the substrate and can exit the optoelectronic semiconductor chip there.

The conversion elements are each designed to convert primary radiation generated by the optoelectronic semiconductor chip during operation into secondary radiation from a wider wavelength range than the primary radiation. In particular, the first and second conversion elements can contain different phosphors, so that they emit secondary radiation in different wavelength ranges. For example, the first conversion element is designed to at least partially convert primary radiation from the wavelength range of blue or ultraviolet light into secondary radiation in the wavelength range of red light. The second conversion element can be designed to convert at least partially the primary radiation into secondary radiation in the wavelength range of yellow and/or green light. Alternatively, it is possible that the second conversion element emits secondary radiation from the wavelength range of red light and the first conversion element emits secondary radiation from the wavelength range of yellow and/or green light.

According to at least one embodiment of the optoelectronic component, the optoelectronic component comprises a carrier on which a plurality of the optoelectronic semiconductor chips is arranged. The semiconductor chips can be arranged one behind the other, in particular along a main extension direction of the carrier. It is especially advantageous if the main extension direction of the semiconductor chips is parallel to the main extension direction of the carrier within the manufacturing tolerance. In this way, especially few optoelectronic semiconductor chips are required for the assembly of an elongated carrier, for example for forming a light thread.

In particular, the carrier can be designed to be transmissive for radiation in places, for example transparent or diffusely scattering. For this purpose, the carrier can be formed with a glass, a plastic or sapphire, for example. Furthermore, the carrier includes contacts and, if necessary, through-connections or conductor paths for the electrical connection of the optoelectronic semiconductor chips.

The substrate can be formed with sapphire or consist of sapphire, for example. It is also possible that the substrate is formed with glass or consists of glass.

Furthermore, a method of manufacturing an optoelectronic component is specified. In particular, an optoelectronic component described here can be manufactured by this method. This means that all features disclosed for the optoelectronic component described here are also disclosed for the method and vice versa.

The method comprises a method step in which a carrier with contacts is provided. The carrier may, for example, have a radiation-transmissive base material to which the contacts are applied. For example, the carrier can be formed with glass.

In a subsequent method step, first conversion elements are applied to the carrier between at least some of the contacts. The application of the conversion elements can be done by a printing process, for example. For this purpose, the conversion elements can, for example, contain a printable matrix material such as silicone or a sol-gel material into which particles of a phosphor are incorporated. In particular, it is also possible to apply conversion elements containing different phosphors to different parts of the substrate.

In a next method step, at least some of the contacts are connected to connection points of an optoelectronic semiconductor chip, so that in at least some of the optoelectronic semiconductor chips a first conversion element is arranged on a side of the semiconductor layer sequence facing away from the substrate between the first connection point and the second connection point of the optoelectronic semiconductor chip. It is possible that the semiconductor chip and the associated first conversion element are spaced from each other in the sense that there is a gap between the first conversion element and the optoelectronic semiconductor chip arranged above it. It is also possible that the conversion element is so thick that a direct contact is created between the semiconductor chip and the associated first conversion element.

As an optoelectronic semiconductor chip, an optoelectronic semiconductor chip described here is particularly suitable, so that all features disclosed for the optoelectronic semiconductor chip are also disclosed for the method and vice versa.

According to at least one embodiment of the method, a second conversion element is applied to at least some of the optoelectronic semiconductor chips on a side facing away from the carrier.

The method described here can be performed in particular in the order described here. In particular, the method step of applying the first conversion element to the carrier is carried out, according to an embodiment of the method, before connecting the optoelectronic semiconductor chips to at least some of the contacts of the carrier. In other words, the conversion elements are then attached to the carrier before the semiconductor chips. The second conversion elements can be attached to the semiconductor chips before or after the carrier is assembled. The method is based inter alia on the idea that a few, particularly long optoelectronic semiconductor chips require fewer assembly steps in the production of, for example, light filaments than would be the case for many, short optoelectronic semiconductor chips. The series connection of such long optoelectronic semiconductor chips requires low operating voltages. The optoelectronic component can therefore be an LED filament with a particular advantage.

### BRIEF DESCRIPTION OF THE DRAWINGS

In the following, the optoelectronic semiconductor chips described here, the optoelectronic components described here and the methods described here are explained in more detail by means of non-limiting embodiments and the corresponding figures.

FIGS. 1A, 1B, 2A, 2B, 2C, 2D show schematic illustrations to explain exemplary embodiments of optoelectronic semiconductor chips described here.

FIGS. 3A, 3B show schematic illustrations to explain optoelectronic components described here.

The schematic illustrations of FIGS. 4A, 4B, 4C, 4D, 4E show steps of a method of manufacturing an optoelectronic semiconductor chip described here of a further exemplary embodiment.

FIG. 5 shows a schematic sectional view to explain an exemplary embodiment of an optoelectronic semiconductor chip described here.

The schematic illustrations in FIGS. 6, 7, 8A, 8B, 9 show exemplary embodiments of optoelectronic components described here.

FIGS. 10A, 10B, 10C show, by means of schematic illustrations, method steps of an exemplary embodiment of a method of manufacturing an optoelectronic component described here.

FIG. 11 shows a schematic illustration of an exemplary embodiment of an optoelectronic component described here.

Identical, similar or equivalent elements are provided with the same reference signs in the figures. The figures and the proportions of the elements represented in the figures among each other are not to be considered as true to scale. Rather, individual elements may be oversized for better representability and/or for better comprehensibility.

### DETAILED DESCRIPTION

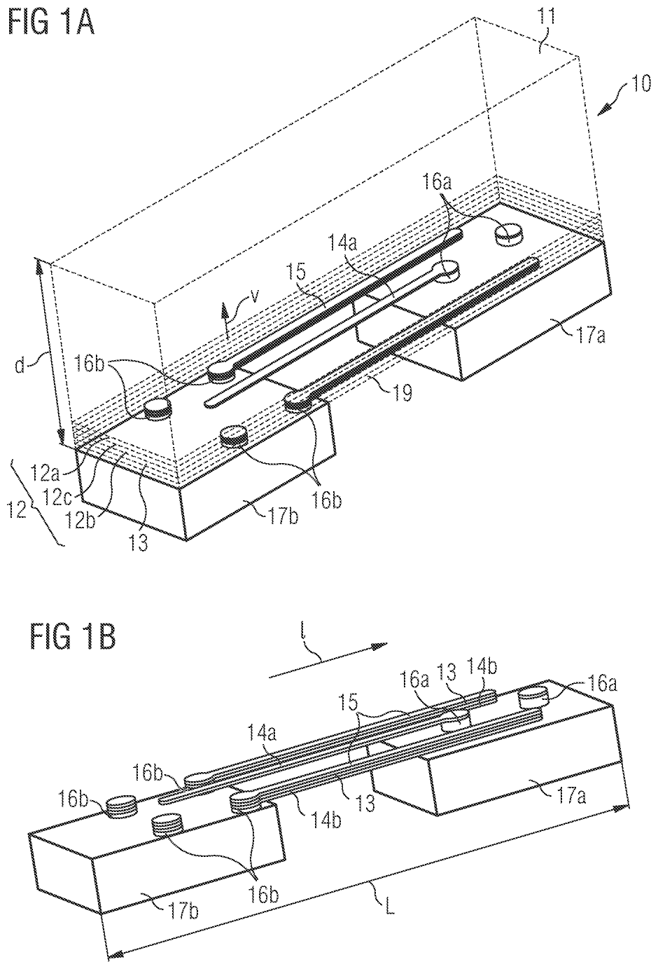

FIG. 1A shows a schematic perspective view of an exemplary embodiment of an optoelectronic semiconductor chip 10 described here.

The optoelectronic semiconductor chip 10 comprises a substrate 11, which for example consists of sapphire, and a thickness d in a vertical direction v, which is parallel to the stacking direction of a semiconductor layer sequence 12. The thickness is at least 300 μm, for example. Furthermore, the thickness can be at most 700 μm, for example.

The semiconductor layer sequence 12, which is based on a III-V compound semiconductor material, for example, is applied to an underside of the substrate 11. The semiconductor layer sequence 12 comprises a first region 12a, which for example is n-conducting, a second region 12b, which for example is p-conducting, and an active region 12c.

The second contact ridge 14b can be electrically connected to the second region 12b of the semiconductor layer sequence 12 via a current expansion layer 13, which is formed, for example, with a TCO (transparent conductive oxide) material such as ITO.

The depicted optoelectronic semiconductor chip 10 is designed for surface mounting via the first connection point 17a, which is provided for contacting the first region 12a, for example, and the second connection point 17b, which is provided for contacting the second region 12b, for example.

The schematic illustration of FIG. 1B shows the contacting of the optoelectronic semiconductor chip for the exemplary embodiment of FIG. 1A. The optoelectronic semiconductor chip comprises first contact points 16a, which establish an electrically conductive connection between the first connection point 17a and the first region 12a. Furthermore, the optoelectronic semiconductor chip comprises second contact points 16b, which establish an electrically conductive connection between the second connection point 17b and the second region 12b. Some of the first and second contact points 16a, 16b are connected to associated first contact ridges 14a and associated second contact ridges 14b, respectively. The contact ridges 14a, 14b extend along a main extension direction l of the optoelectronic semiconductor chip 10 over at least 50% of the length L of the optoelectronic semiconductor chip.

The first and second contact points 16a, 16b form contact pins, which can be particularly high. In particular, the height of the contact points 16a, 16b in vertical direction v can be large against their diameter. For example, the contact points 16a, 16b are cylindrical. The contact points 16a, 16b can be formed with a ductile metal, which can include nickel and/or copper and/or gold, for example. The associated contact ridges 14a, 14b can be formed with the same material. The contact points 16a, 16b and/or the contact ridges 14a, 14b can thus easily transfer mechanical forces acting on the semiconductor chip 10 to a carrier to which the semiconductor chips 10 are attached and do not break when the temperature of the semiconductor chip 10 changes.

At the upper side of the second contact ridges 14b and the second contact points 16b facing the semiconductor layer sequence 12, there is a blocking layer 15 for current, which prevents the generation of electromagnetic radiation directly above the second contact points 16b and the second contact ridges 14b.

The blocking layer 15 can be formed with SiO₂, for example, wherein the blocking layer 15 can be structured by etching.

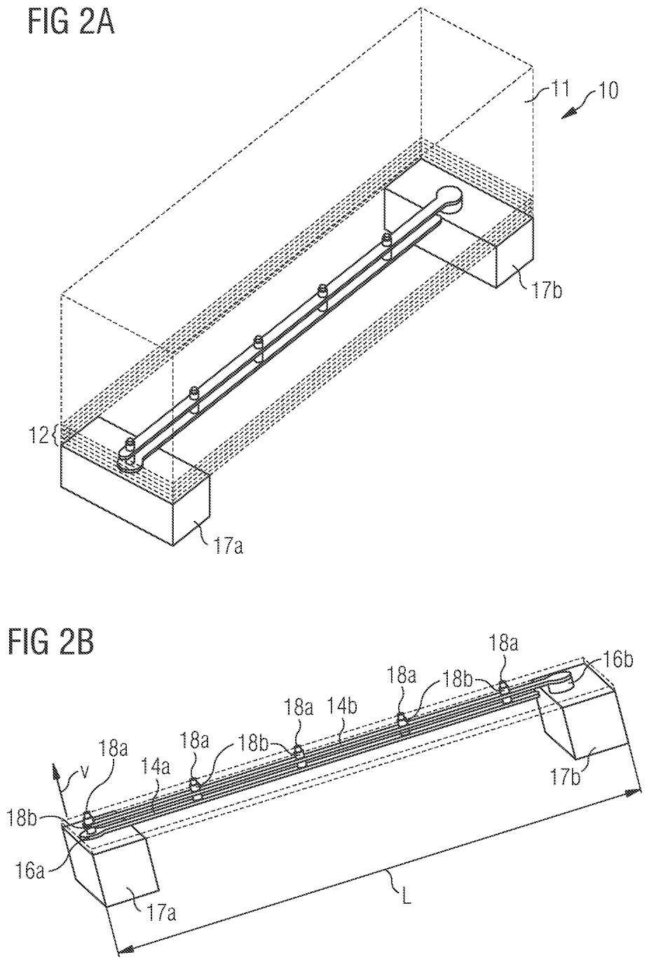

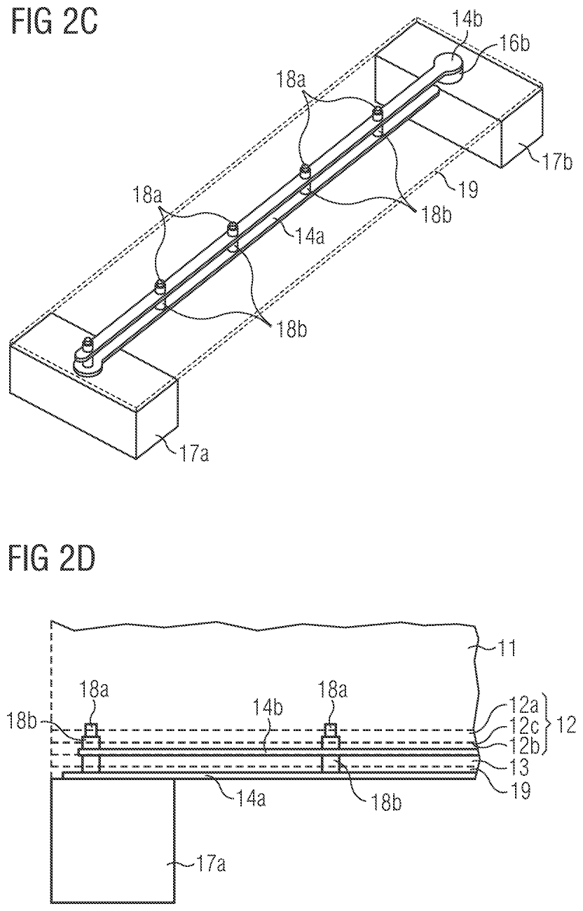

In connection with the schematic illustrations of FIGS. 2A, 2B, 2C and 2D, another exemplary embodiment of an optoelectronic semiconductor chip described here is explained. In contrast to the optoelectronic semiconductor chip 10 of FIGS. 1A and 1B, the first contact ridges 14a and the second contact ridges 14b are arranged one above the other in the vertical direction v, i.e. vertically overlapping one another. For this purpose, through-connections 18a can extend from the first contact ridge 14a, which is provided for n-side contacting, for example, through the second contact ridge 14b into the first region 12a of the semiconductor layer sequence 12. The through-connections 18a can be covered by an insulation 18b and thus be electrically insulated from the second contact ridge 14b. The through-connections can be made of the same material as the contact points 16a, 16b. Both contact ridges 14a, 14b can extend over almost the entire length of the optoelectronic semiconductor chip 10. For example, each contact ridge 14a, 14b extends over at least 90% of the length L of the optoelectronic semiconductor chip 10.

At least in some areas, the optoelectronic semiconductor chip may have a mirror 19 on its underside facing away from the substrate 11, which is intended to reflect electromagnetic radiation generated or to be detected in the semiconductor chip. The mirror 19 can be formed over a large area on the underside of the semiconductor chip between the connection points 17a and 17b and cover these completely, or the mirror 19 is only arranged in the area of the contact ridges 14a, 14b and overlaps these vertically.

As can be seen, for example, in the schematic sectional view of FIG. 2D, the through-connections 18a can extend into the substrate 11 to mechanically stabilize the optoelectronic semiconductor chip. They then anchor the layer sequence 12 to substrate 11.

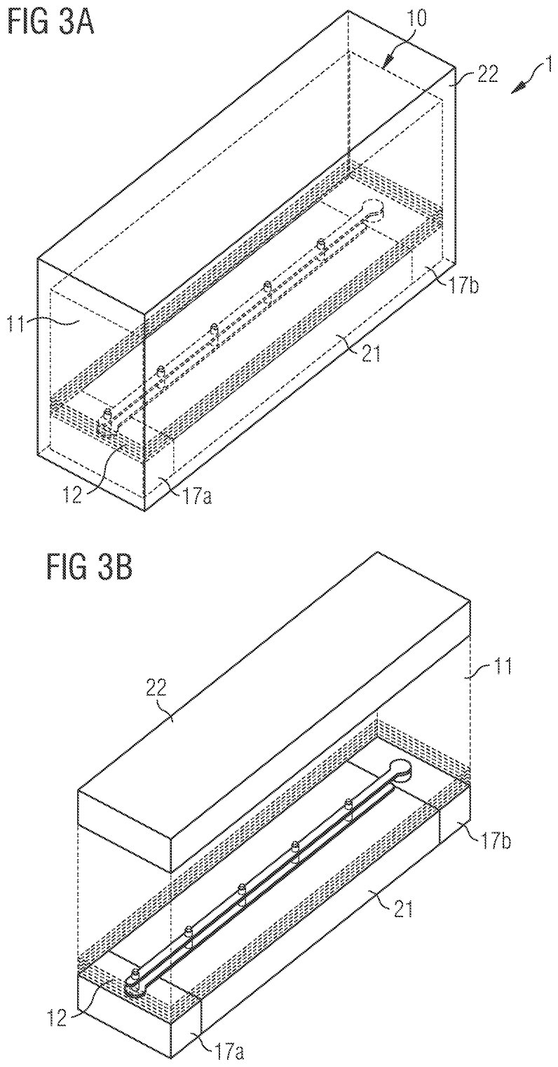

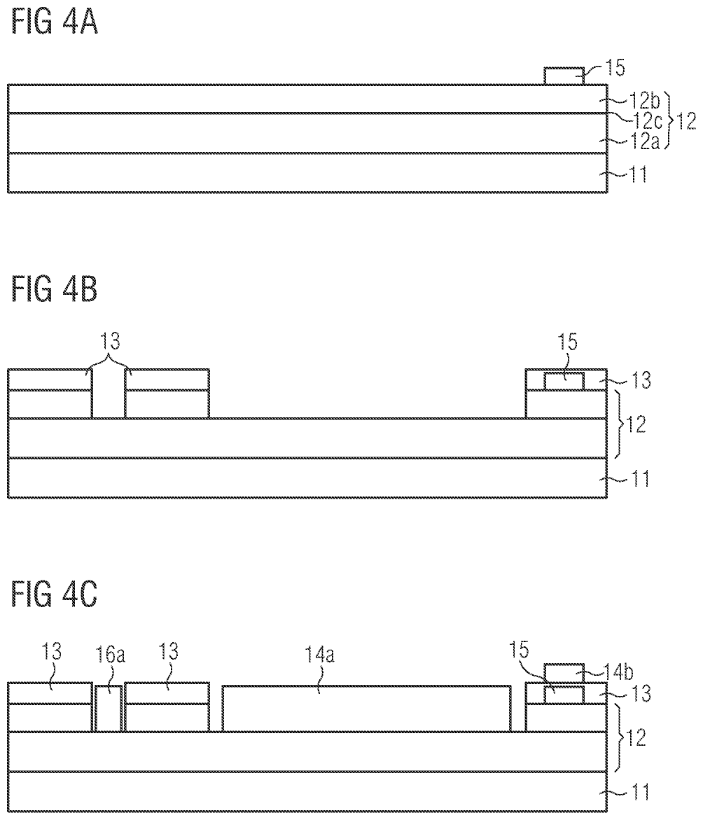

In connection with the schematic illustrations of FIGS. 3A and 3B, two exemplary embodiments of an optoelectronic component described here are explained in more detail. In the exemplary embodiment of FIG. 3A, the optoelectronic component 1 comprises an optoelectronic semiconductor chip 10 as described in connection with FIG. 1 or 2, for example. The optoelectronic semiconductor chip 10 is surrounded by a second conversion element 22 on its side surfaces and on its top side of the substrate 11 facing away from the semiconductor layer sequence 12. The second conversion element 22 comprises, for example, a matrix material in which particles of a phosphor are incorporated. For example, the matrix material is a silicone.

On the underside of the semiconductor layer sequence 12 facing away from the substrate 11, a first conversion element 1 is arranged in direct contact with the semiconductor chip between the two connection points 17a and 17b. The two conversion elements 21, 22 may differ from each other with respect to the phosphors used. In particular, the first conversion element 21 can contain a material that is a particularly good thermal conductor and thus contribute to heat dissipation from the optoelectronic semiconductor chip 10.

The first conversion element 21, for example, is configured to emit green secondary radiation, the second conversion element 22 is then configured to emit red secondary radiation. For example, blue light is generated in the active region 12c of the optoelectronic semiconductor chip 10. Because the entire outer surface of the optoelectronic semiconductor chip 10 in the exemplary embodiment of FIG. 3A is surrounded by material of one of the conversion elements 21, 22, no blue secondary light (so-called blue piping) is produced.

In contrast to the exemplary embodiment of FIG. 3A, the second conversion element 22 is only applied to the side of the substrate 11 facing away from the semiconductor layer sequence in the exemplary embodiment of FIG. 3B. In this exemplary embodiment, the side surfaces of the substrate 11 remain free of conversion material. The first conversion element 21 remains on the underside of the optoelectronic semiconductor chip. Such an optoelectronic component is particularly easy to manufacture.

It has been found that the spatial separation of different conversion elements, i.e. in this case the first conversion element 21 and the second conversion element 22, increases the efficiency of light generation. Due to this spatial separation, already converted light has a lower probability to lose energy at another conversion element in a further inelastic scattering process. The heat dissipation of the conversion elements is also optimized by the large-area contact at the optoelectronic semiconductor chip 1.

In connection with the schematic sectional views of FIGS. 4A to 4E, an exemplary embodiment of a method of manufacturing a semiconductor chip described here is explained in more detail.

In the method, a substrate 11 is first provided, which can be a growth substrate formed with sapphire. The semiconductor layer sequence 12 comprising the first region 12a, the second region 12b and between them the active region 12c is epitaxially deposited on the substrate 11.

A blocking layer 15 is applied to the top side of the semiconductor layer sequence 12 facing away from the substrate 11.

In the next method step, FIG. 4B, a coating of material of the current expansion layer 13, which is formed with ITO for example, is applied. Subsequently, the semiconductor layer sequence 12 is structured so that the first region 12a is exposed in places. The structuring is done by etching, for example.

In the method step described in connection with FIG. 4C, a photo technique is used to apply metals for the contact ridges 14a, 14b and contact points 16a, 16b.

In the next method step, FIG. 4D, the mirror 19 is applied and structured by etching. Finally, FIG. 4E, the first connection point 17a and the second connection point 17b are created and electrically connected to the contact ridges 14a, 14b and the contact points 16a, 16b.

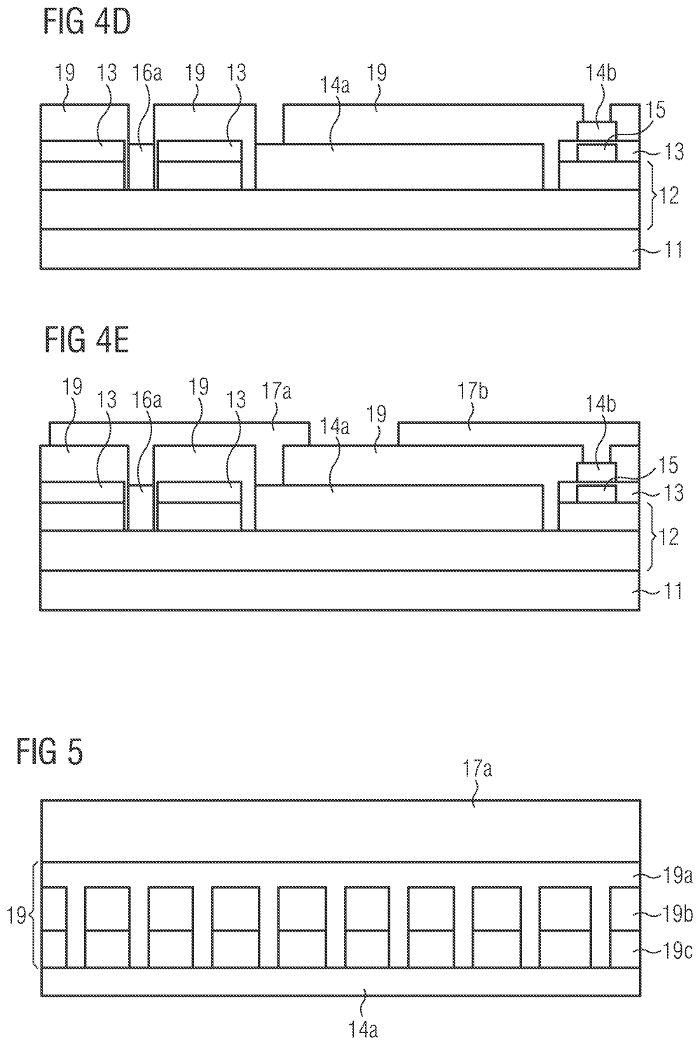

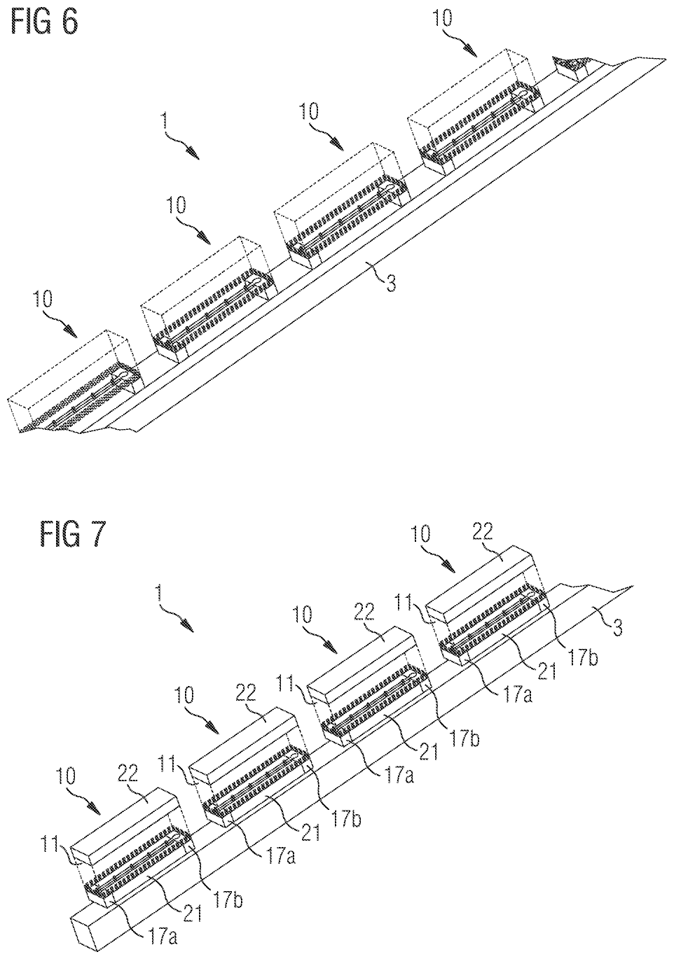

Using the schematic sectional view of FIG. 5, a further exemplary embodiment of an optoelectronic semiconductor chip described here is explained in more detail. In this exemplary embodiment, the mirror 19 is formed with three mirror layers, the first mirror layer 19a, the second mirror layer 19b and the third mirror layer 19c. The mirror 19 comprises, with the second mirror layer 19b and the third mirror layer 19c, two Bragg mirrors. The second mirror layer 19b and the third mirror layer 19c are combined with the first mirror layer 19a, which is a metallic layer.

For example, the first mirror layer 19a is formed with aluminum. The first mirror layer 19a can metallize a large area of one or both of the connection points, FIG. 5 shows the first connection point 17a. This favors the heat dissipation of the optoelectronic semiconductor chip during operation. Via openings in the second mirror layer 19b and the third mirror layer 19c, the first mirror layer 19a is guided to the associated contact ridge, in this case the first contact ridge 14a. The openings can be cylindrical or form elongated trenches.

The second mirror layer and the third mirror layer are, for example, each formed by Bragg mirrors with eight pairs of TiO₂/SiO₂ each. In such a mirror 19, the first mirror layer 19a is used for cooling the chip, for the electrical connection between the contact ridge and the connection point, and for reflecting electromagnetic radiation.

In connection with the schematic illustration in FIG. 6, an exemplary embodiment of an optoelectronic component described here is shown. In the optoelectronic component, several optoelectronic semiconductor chips are formed one behind the other on an elongated carrier 3, which is, for example, transmissive for radiation. The optoelectronic semiconductor chips 10 are not followed by a conversion element. All in all, the optoelectronic component 1 of the exemplary embodiment of FIG. 6 forms a blue shining LED filament, for example.

In contrast to the exemplary embodiment of FIG. 6, the exemplary embodiment of FIG. 7 shows an optoelectronic component 1 in which a first conversion element 21 and a second conversion element 22, as described in connection with FIG. 3B, for example, are arranged downstream of each optoelectronic semiconductor chip 10. It is possible that the materials for forming the first conversion elements 21 and the second conversion elements 22 are alternately exchanged. This means that for the semiconductor chip 10 shown on the far left, for example, the first conversion element 21 can re-emit red light and the second conversion element 22 can re-emit green light. For the semiconductor chip shown on the right of the latter, this may be reversed so that the first conversion element 21 re-emits green light and the second conversion element 22 re-emits red light. This sequence can be continued. In this way, particularly good light mixing takes place in the carrier 3, which can be a glass rod, for example, so that the optoelectronic component 1 can emit particularly homogeneous white mixed light.

In contrast to the exemplary embodiment of FIG. 7, the semiconductor chips 10 in the exemplary embodiment of FIGS. 8A and 8B are mounted horizontally on the carrier 3. They are electrically connected to the contacts 31 of the carrier 3, for example, via connecting means 32. For example, the connecting means 32 can be a solder.

In the exemplary embodiment of FIG. 9, the semiconductor chips 10 with the first and second conversion elements are mounted on a carrier 3, which has a reflector laterally surrounding the semiconductor chips 10. In this way, the optoelectronic component 1 can, for example, form a light source that can be used in a spot lamp.

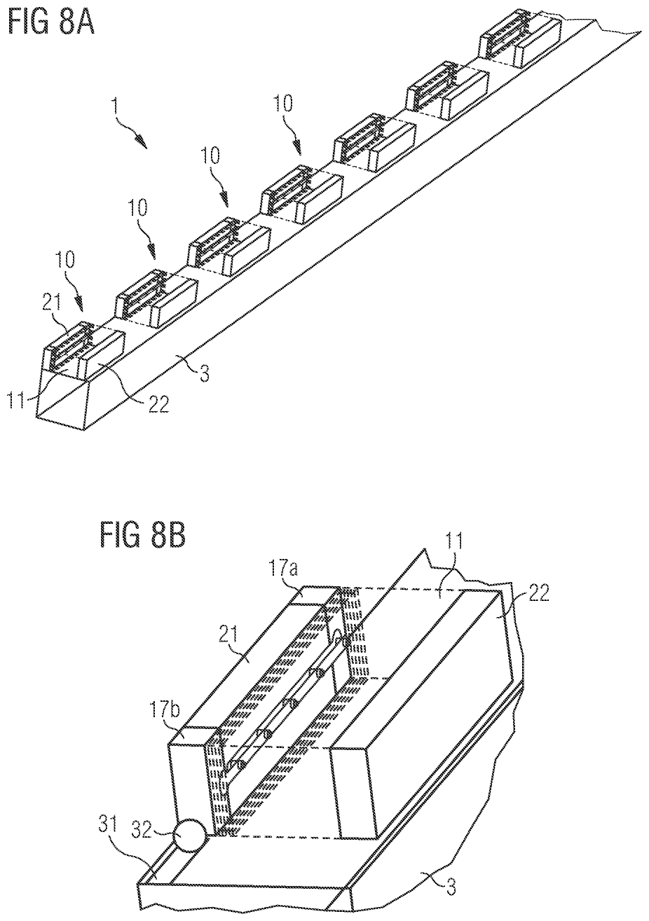

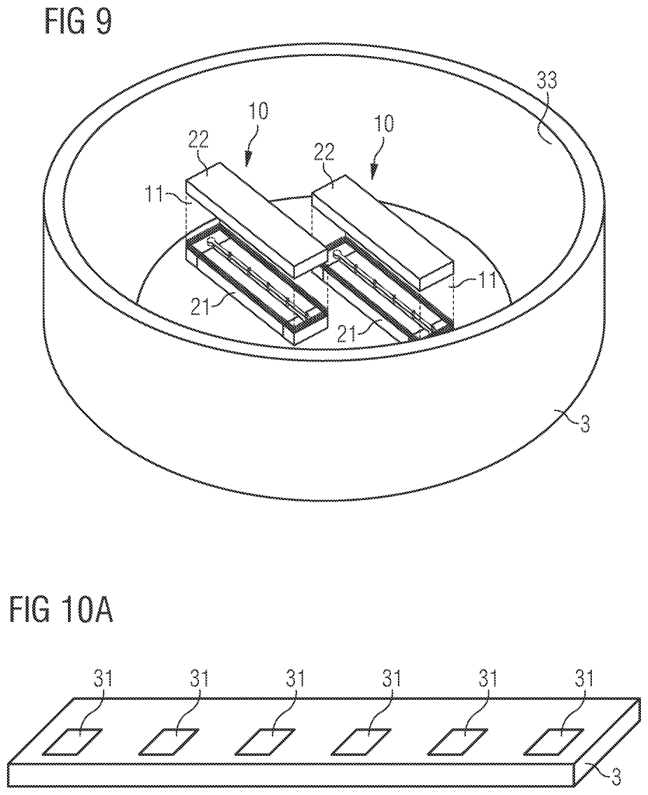

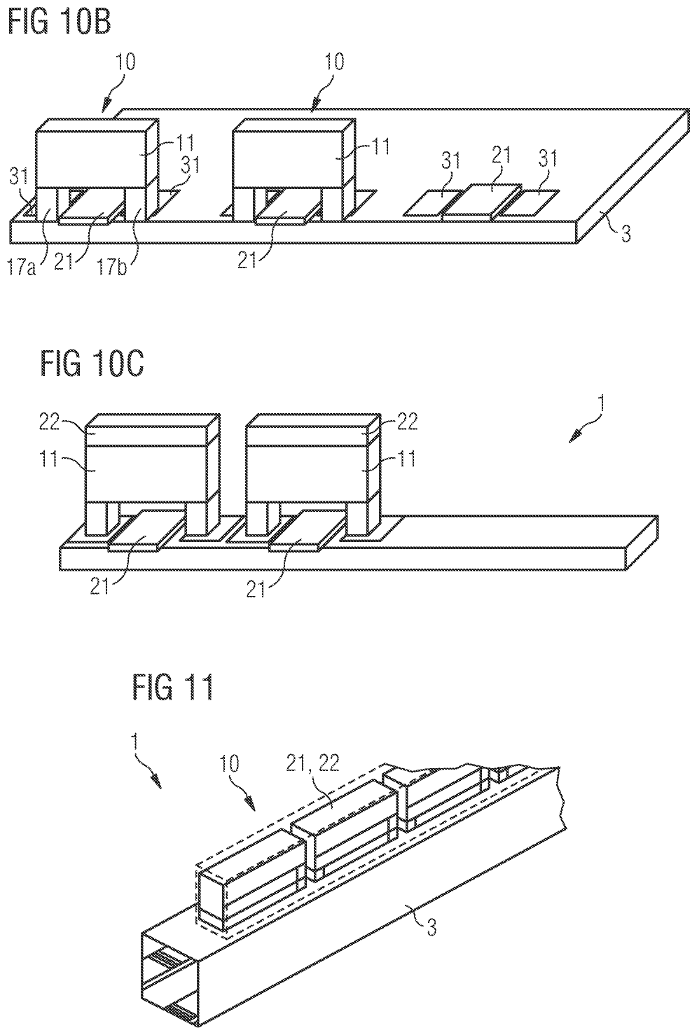

In connection with the schematic illustrations of FIGS. 10A to 10C, an exemplary embodiment of a method of manufacturing an optoelectronic component described here is explained in more detail. In this method, a carrier 3, which can be a glass plate with contacts 31, is first provided. This is shown schematically in FIG. 10A. Subsequently, FIG. 10 B, first conversion elements 21 can be applied, for example by printing on the carrier 3 between adjacent contacts 31. Subsequently, optoelectronic semiconductor chips 10 are placed and fixed on the carrier 3 in such a way that the connection points 17a, 17b are electrically conductively connected to associated contacts 31 of the carrier 3 and the first conversion elements 21 are arranged between the substrate 11 and the carrier 3 on the underside of the semiconductor chips 10.

In a previous or subsequent method step, second conversion elements 22 can be applied to the semiconductor chips 10, resulting in an optoelectronic component 1 as shown in connection with FIG. 10C.

In connection with FIG. 11, another exemplary embodiment of an optoelectronic component 1 described here is explained in more detail. In this exemplary embodiment, several semiconductor chips 10 are encased over their entire surface by a conversion element 21, 22. The carrier 3 remains free of the conversion material. Since the conversion element 21, 22 is also located on the underside of the semiconductor chips 10 between the semiconductor chips and carrier 3, encasing the entire arrangement, i.e. semiconductor chips 10 with carrier 3, in conversion material can be omitted without causing emission of less homogeneous light. Light mixing can also take place in the carrier 3, which can be designed as a glass rod. Since such a glass rod represents a large emission volume, the radiation in the far field is homogeneous, i.e. homogeneous white mixed light is perceived by the observer.

The features and exemplary embodiments described in connection with the figures can be combined with each other according to further exemplary embodiments, even if not all combinations are explicitly described. Furthermore, the exemplary embodiments described in connection with the figures may alternatively or additionally have further features as described in the general part.

This patent application claims the priority of German patent application 102018119438.2, the disclosure content of which is hereby incorporated by reference.

The invention is not limited to the exemplary embodiments by the description based on the same. Rather, the invention comprises any new feature as well as any combination of features, which in particular includes any combination of features in the claims, even if this feature or this combination itself is not explicitly stated in the claims or exemplary embodiments.

### LIST OF REFERENCE SIGNS

1 optoelectronic component
10 optoelectronic semiconductor chip
11 substrate
12 semiconductor layer sequence
12a first region (for example n-conducting)
12b second region (for example p-conducting)
12c active region
13 current expansion layer
14a first contact ridge (for example n-conducting)
14b second contact ridge (for example p-conducting)
15 blocking layer for current
16a first contact point (for example n-conducting)
16b second contact point (for example p-conducting)
17a first connection point (for example n-conducting)
17b second connection point (for example p-conducting)
18a through-connection
18b insulation
19 mirror
19a first mirror layer
19b second mirror layer
19c third mirror layer
19d opening
21 first conversion element
22 second conversion element
3 carrier
31 contact
32 connecting means
33 reflector
d thickness of the substrate
v vertical direction
l main extension direction of the semiconductor chip
L length of the semiconductor chip

1. An optoelectronic semiconductor chip comprising:
a substrate that is transmissive for radiation;
a semiconductor layer sequence having a first region of a first conductivity type, a second region of a second conductivity type, and an active region between the first region and the second region;
a first contact ridge configured to energize the first region;
a second contact ridge configured to energize the second region;
a first connection point configured to contact the first contact ridge from outside the optoelectronic semiconductor chip; and
a second connection point configured to contact the second contact ridge from outside the optoelectronic semiconductor chip;
wherein:
the first contact ridge and the second contact ridge each extend over at least 50% of the length of the semiconductor chip; and
the first contact ridge and the second contact ridge vertically overlap, wherein at least one through-connection extends from the first contact ridge through the second contact ridge into the first region.

2. The optoelectronic semiconductor chip according to claim 1,
wherein the first contact ridge vertically overlaps with the second connection point, the second contact ridge vertically overlaps with the first connection point, or combinations thereof.

3. The optoelectronic semiconductor chip according to claim 1,
wherein the first contact ridge vertically overlaps with the second connection point, and wherein the second contact ridge vertically overlaps with the first connection point.

4. The optoelectronic semiconductor chip according to claim 1,
further comprising exactly one additional first contact ridge and exactly one additional second contact ridge.

5. The optoelectronic semiconductor chip according to claim 1,
wherein the substrate has a thickness of at least 300 μm.

6. The optoelectronic semiconductor chip according to claim 1,
further comprising a mirror between the first contact ridge and the first connection point, between the second contact ridge and the second connection point, or combinations thereof; wherein the mirror comprises a first mirror layer which is metallic, a second mirror layer which is a Bragg mirror, and a third mirror layer which is a Bragg mirror.

7. The optoelectronic semiconductor chip according to claim 6,
wherein the first mirror layer extends through openings in the second mirror layer and the third mirror layer and provides an electrically conductive connection between the first contact ridge and the first connection point, between the second contact ridge and the second connection point, or combinations thereof.

8. The optoelectronic semiconductor chip according to claim 1,
wherein the first connection point and the second connection point are configured for surface mounting.

9. An optoelectronic component comprising:
at least one optoelectronic semiconductor chip comprising:
a substrate that is transmissive for radiation;
a semiconductor layer sequence having a first region of a first conductivity type, a second region of a second conductivity type, and an active region between the first region and the second region;
a first contact ridge configured to energize the first region;
a second contact ridge configured to energize the second region;
a first connection point configured to contact the first contact ridge from outside the optoelectronic semiconductor chip; and
a second connection point for contacting the second contact ridge from outside the optoelectronic semiconductor chip;
wherein the first contact ridge and the second contact ridge each extend over at least 50% of the length of the optoelectronic semiconductor chip;
a first conversion element on a side of the semiconductor layer sequence facing away from the substrate between the first connection point and the second connection point of at least one of the semiconductor chips a second conversion element on a side of the substrate of at least one of the semiconductor chips facing away from the semiconductor layer sequence, or combinations thereof.

10. The optoelectronic component according to claim 9,
further comprising a carrier on which a plurality of the optoelectronic semiconductor chips is arranged.

11. The optoelectronic component according to claim 10,
wherein the optoelectronic semiconductor chips are arranged along a main extension direction of the carrier.

12. The optoelectronic component according to claim 10,
wherein the carrier is partially transmissive for radiation.

13. A method of manufacturing an optoelectronic component comprising, wherein the method comprises:
providing a carrier with contacts;
applying first conversion elements to the carrier between at least some of the contacts;
connecting at least some of the contacts to the connection points of an optoelectronic semiconductor chips, so that in at least one of the optoelectronic semiconductor chips a first conversion element is arranged on a side of the semiconductor layer sequence facing away from a substrate of the optoelectronic semiconductor chip between a first connection point of the optoelectronic semiconductor chip and a second connection point of the optoelectronic semiconductor chip;
wherein said optoelectronic chip comprises:
the substrate, wherein the substrate is transmissive for radiation;
a semiconductor layer sequence having a first region of a first conductivity type, a second region of a second conductivity type, and an active region between the first region and the second region;
a first contact ridge for energizing the first region;
a second contact ridge for energizing the second region;
the first connection point for contacting the first contact ridge from outside the optoelectronic semiconductor chip; and
the second connection point for contacting the second contact ridge from outside the optoelectronic semiconductor chip;
wherein the first contact ridge and the second contact ridge each extend over at least 50% of the length of the semiconductor chip.

14. The method according to claim 13, further comprising a second conversion element applied to at least some of the optoelectronic semiconductor chips on a side facing away from the carrier.
